(19) United States
(12) Patent Application Publication
(10) Pub. No.: US 2025/0212669 A1
(43) Pub. Date: Jun. 26, 2025

(54) LIGHT EMITTING DISPLAY DEVICE

(71) Applicant: LG Display Co., Ltd., Seoul (KR)

(72) Inventors: JiYeon PARK, Paju-si (KR); Yeonsuk KANG, Paju-si (KR); Jonghyun PARK, Paju-si (KR); DaeYun HAN, Paju-si (KR)

(21) Appl. No.: 18/961,354

(22) Filed: Nov. 26, 2024

(30) Foreign Application Priority Data
Dec. 21, 2023 (KR) 10-2023-0188062

(51) Int. Cl. H10K 59/80; H10K 59/122; H10K 59/38

(52) U.S. Cl. CPC H10K 59/8792; H10K 59/122; H10K 59/38

(57) ABSTRACT

The present disclosure relates to light emitting display device. A light emitting display device according to the present disclosure includes a display panel including a plurality of pixels arrayed in a matrix manner; a cover plate covering the display panel; a slit disposed between the pixels neighboring in the first direction on the cover plate; and a light absorbing material filled in the slit.

### CROSS-REFERENCE TO RELATED APPLICATIONS

This application claims the benefit of the Korean Patent Application No. 10-2023-0188062 filed on Dec. 21, 2023, which is hereby incorporated by reference as if fully set forth herein.

### BACKGROUND

### Technical Field

The present disclosure relates to a light emitting display device in which color purity is improved.

### Description of the Related Art

Recently, a head mount display (HMD) including an organic light emitting diode display has been developed. The HMD is a wearable monitor device for virtual reality (VR) or augmented reality (AR) that is worn in the form of glasses or a helmet so it focuses on a distance close to the user's eyes. Such a head-mounted display may be equipped with a small organic light emitting diode display with high resolution property.

Particularly, in an ultra-high-density resolution display device having a pixel density of 4K PPI (pixel per inch) or more, since the size of the pixel may be getting smaller, color mixing may be occurred between two neighboring pixel, causing deterioration in image quality. To improve these problems, a method of increasing brightness may be considered, but this method has the problem of increasing the power consumption. Therefore, structural improvements may be needed to provide image quality with brighter luminance and clearer color purity with the same power consumption.

### BRIEF SUMMARY

Various embodiments of the present disclosure, as for solving the problems described above, provide a top emission type light emitting display device or a top emission type transparent light emitting display device having high luminance compared to power consumption and of which color purity is enhanced or improved.

One or more example embodiments of the present disclosure may provide a top emission type light emitting display device or a top emission type transparent light emitting display device that improve color purity by preventing color mixing between very densely packed pixels in an ultra-high-resolution structure, and enable low-power operation due to high luminance with the same power consumption.

In order to accomplish the above mentioned purposes of the present disclosure, a light emitting display device according to the present disclosure comprises: a display panel including a plurality of pixels arrayed in a matrix manner; a cover plate covering the display panel; a slit disposed between two pixels neighboring in a first direction on the cover plate; and a light absorbing material filled in the slit.

In an example, the slit has a depth equal to or smaller than a thickness of the cover plate.

In an example, the depth of the slit is 80% to 100% of the thickness of the cover plate.

In an example, the slit includes: a first side surface extending from an upper surface of the cover plate to a first end recessed a selected depth along a direction of the depth; a second side surface separated from the first side surface with a selected width, extending from the upper surface of the cover plate to a second end recessed the selected depth along the direction of the depth, and facing the first side surface; a bottom surface extending from the first end to the second end; and a top surface facing the bottom surface and setting on the upper surface of the cover plate.

In an example, the first side surface and the second side surface are parallel to each other, as vertical surfaces.

In an example, any one of the first side surface and the second side surface is a slanted plane, and the other is a vertical plane.

In an example, the first side surface and the second side surface are slanted planes.

In an example, a size of the top surface is different from a size of the bottom surface.

In an example, the display panel includes: an anode electrode disposed on each pixel; a bank covering circumference of the anode electrode; an emission layer disposed on the anode electrode; and a cathode electrode disposed on the emission layer. The slit has a width corresponding to the bank.

In an example, the slit has a width 5% to 10% wider than the bank. The bank is overlapped with a middle portion of the slit.

In an example, the display panel includes: a substrate; a driving element layer disposed on the substrate; a light emitting element layer disposed on the driving element layer; an encapsulation layer disposed on the light emitting element layer; and a color filter layer disposed on the encapsulation layer. The cover plate is adhered on the color filter layer with a transparent optical adhesive.

In an example, the color filter layer includes a first color filter, a second color filter and a third color filter corresponding to each pixel. The slit is disposed between the first color filter and the second color filter, between the second color filter and the third color filter, and between the third color filter and the first color filter.

In an example, the light absorbing material has a refractive index less than the cover plate.

In an example, the cover plate includes a transparent material of which refractive index is 1.5 to 1.9. The light absorbing material includes a black resin material of which refractive index is 1.2 to 1.4.

In an example, the display panel includes: a display area providing video images; and a non-display area surrounding the display area. The cover plate has an area larger than the display area and is disposed on the display area. The slit is disposed within the display area on the cover plate.

The light emitting display device according to the present disclosure may include a black matrix that separates boundaries between pixels on a cover glass substrate (or cover glass) attached to the top of a display panel equipped with a color filter Accordingly, color purity of each pixel may be improved by preventing light from being mixed at the boundary between the two neighboring pixels.

The light emitting display device according to the present disclosure may provide brighter luminance with the same power consumption by that the color filter disposed in each pixel may have an area corresponding to the maximum size of the light emitting area of each pixel. In addition, voids or gaps may be formed between pixels on the cover glass substrate placed on the color filter, and the voids are filled with a black resin material to provide a black matrix, thereby preventing color mixing at the boundary between pixels. Therefore, the light emitting display device according to the present disclosure may provide high luminance and improved color purity with low power consumption, providing excellent image quality with low-power operation.

In addition to the effects of the present disclosure mentioned above, other features and advantages of the present disclosure are described below, or may be clearly understood by those skilled in the art from such descriptions and explanations.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plane view illustrating a schematic structure of a light emitting display device according to an embodiment of the present disclosure.

FIG. 2 is a circuit diagram illustrating a structure of one pixel disposed in a light emitting display device according to an embodiment of the present disclosure.

FIG. 3 is an enlarged plan view illustrating a structure of three pixels sequentially disposed in the light emitting display device according to an embodiment of the present disclosure.

FIG. 4 is a cross-sectional view, cutting along line I-I′ in FIG. 3, for illustrating a structure of one pixel in a light emitting display device according to an embodiment of the present disclosure.

FIG. 5 is a plan view illustrating a structure of three pixels sequentially arrayed in a light emitting display device according to a first embodiment of the present disclosure.

FIG. 6 is an enlarged cross-sectional view, cutting along line II-II′ of FIG. 5, for illustrating a structure of three pixels sequentially arrayed in a light emitting display device according to a first embodiment of the present disclosure.

FIG. 7 is an enlarged cross-sectional view, cutting along line II-II′ of FIG. 5, for illustrating a structure of three pixels sequentially arrayed in a light emitting display device according to a second embodiment of the present disclosure.

FIG. 8 is an enlarged cross-sectional view, cutting along line II-II′ of FIG. 5, for illustrating a structure of three pixels sequentially arrayed in a light emitting display device according to a third embodiment of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, (e.g., length, width, height, thickness, radius, diameter, area, etc.), ratios, angles, numbers, and the like, which are illustrated in the drawings in order to describe various example embodiments of the present disclosure, are merely given by way of example. Therefore, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification unless otherwise specified. In the following description, where the detailed description of the relevant known function or configuration may unnecessarily obscure an important point of the present disclosure, a detailed description of such known function of configuration may be omitted.

Reference will now be made in detail to the exemplary embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to distinguish one element from another, and not to define a particular nature, order, sequence, or number of the elements. Where an element is described as being “linked,” “coupled” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Hereinafter, an example of a display apparatus according to the present disclosure will be described in detail with reference to the attached drawings. Wherever possible, the same reference numbers will be used throughout the drawings to refer to the same or like parts.

Hereinafter, referring to the attached figures, the present disclosure will be explained. Since a scale of each of elements shown in the accompanying drawings may be different from an actual scale for convenience of description, the present disclosure is not limited to the scale shown in the drawings.

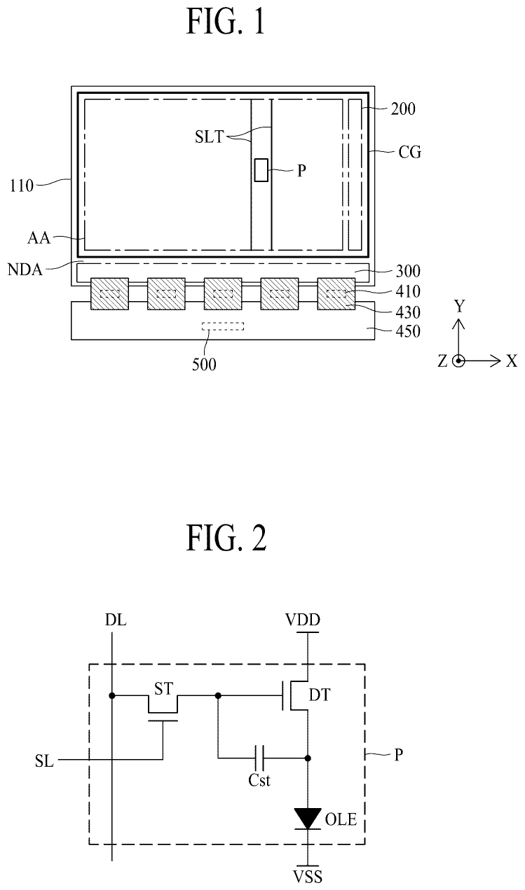

FIG. 1 is a plane view illustrating a schematic structure of a light emitting display device according to an embodiment of the present disclosure. In FIG. 1, X-axis refers to the direction parallel to the scan line, Y-axis refers to the direction of the data line, and Z-axis refers to the height direction of the display device.

Referring to FIG. 1, the electroluminescence display comprises a substrate 110, a cover plate CG, a gate (or scan) driver 200, a pad portion 300, a source driving IC (Integrated Circuit) 410, a flexible circuit film 430, a circuit board 450, and a timing controller 500.

The substrate 110 may include an electrical insulating material or a flexible material. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material.

The substrate 110 may include a display area AA and a non-display area NDA. The display area AA, which is an area for representing the image information or the video images, may be defined as the majority middle area of the substrate 110, but it is not limited thereto. In the display area AA, a plurality of pixels P are arrayed in a matrix manner. Further, a plurality of scan lines (or gate lines), a plurality of data lines may be disposed as crossing each other. Each of pixels P may be disposed at the crossing area of the scan line running to X-axis and the data line running to Y-axis.

Here, the pixel P may represent any one of color among red, green and blue or red, green, blue or white. A red pixel, a green pixel and a blue pixel may be gathered or a red pixel, a green pixel, a blue pixel and a white pixel may be gathered to form one unit pixel. For example, each of the pixels representing each color may be called as a ‘sub-pixel,’ and it may be explained that these ‘sub-pixels’ form one ‘pixel.’ As another example, it may be explained that pixels representing each color are called as ‘pixels P,’ and three or four of these ‘pixels P’ are gathered to form one ‘unit pixel.’ Hereinafter, the latter case will be described.

The non-display area NDA, which is an area not representing the video images, may be defined at the circumference areas of the substrate 110 surrounding all or some of the display area AA. In the non-display area NDA, the gate driver 200 and the pad portion 300 may be formed or disposed.

The gate driver 200 may supply the scan (or gate) signals to the scan lines SL according to the gate control signal received from the timing controller 500 through the pad portion 300. The gate driver 200 may be formed at the non-display area NDA at any one outside of the display area DA on the substrate 110, as a GIP (Gate driver In Panel) type. GIP type means that the gate driver 200 is directly formed on the substrate 110. For example, the gate driver 200 may be configured with shift registers. In the GIP type, the transistors for shift registers of the gate driver 200 are directly formed on the upper surface of the substrate 110.

The pad portion 300 may be disposed in the non-display area NDA at one side edge of the display area AA of the substrate 110. The pad portion 300 may include data pads connected to each of the data lines DL, driving current pads connected to the driving current lines, a high-potential pad receiving a high potential voltage, and a low-potential pad receiving a low potential voltage.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible circuit film 430 as a COF (Chip On Film) or COP (Chip On Plastic) type.

The flexible circuit film 430 may include a plurality of first link lines connecting the pad portion 300 to the source driving IC 410, and a plurality of second link lines connecting the pad portion 300 to the circuit board 450. The flexible circuit film 430 may be attached on the pad portion 300 using an anisotropic conducting film, so that the pad portion 300 may be connected to the first link lines of the flexible circuit film 430.

The circuit board 450 may be attached to the flexible circuit film 430. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be integrated with the source driving IC 410 into one driving chip and may be mounted on the substrate 110 to be connected to the pad unit 300.

The cover plate CG may be disposed on the substrate 110. The cover plate CG may have slightly larger size than the display area AA, and may be joined with the substrate 110 as completely covering the display area AA. When the gate driver 200 is formed directly on the substrate 110 using the GIP method, the cover plate CG may be arranged to also cover the gate driver 200. Since the pad portion 300 is a portion to which the flexible circuit film 430 is attached, the cover plate CG may not cover the pad portion 300.

A plurality of slits SLT may be disposed on the top surface of the cover plate CG. Each of slit SLT may be disposed between neighboring two columns of pixel P. That is, each slit SLT may be disposed at left side and right side of the pixel P, respectively. The slit SLT may be a groove formed in the cover plate CG, and has a thin trench shape recessed by a certain thickness of the cover plate CG, or a through-bar shape with the entire thickness of the cover plate CG removed. Since the slit SLT may be formed only in the display area of the cover plate CG, the cover plate CG may be not separated by the slit SLT. In addition, the inside of the slit SLT may be filled with black resin material. To further elaborate, when the inside of the slit (SLT) is filled with black resin material, this does not imply a narrow interpretation of the slit being “filled” exclusively with the black resin material to the exclusion of other materials. Namely, the term “filled with,” as used herein, is intended to encompass a broad range of conditions, including but not limited to “partially filled with,” “substantially filled with,” “completely filled with,” or “exclusively filled with.” The detailed structure of the slit may be described below.

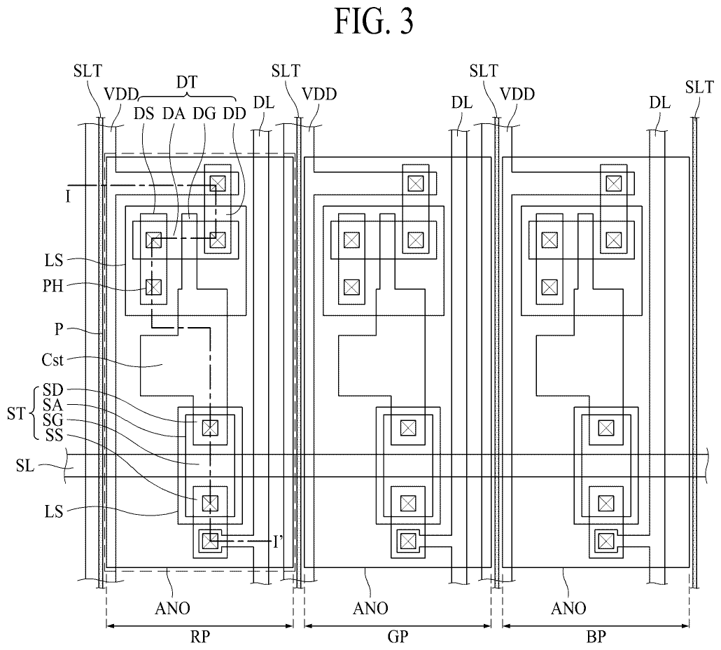

Hereinafter, referring to FIGS. 2 to 4, a detailed structure of a light emitting display device according to an embodiment of the present disclosure will be explained. FIG. 2 is a circuit diagram illustrating a structure of one pixel disposed in a light emitting display device according to an embodiment of the present disclosure. FIG. 3 is an enlarged plan view illustrating a structure of three pixels sequentially disposed in the light emitting display device according to an embodiment of the present disclosure.

Referring to FIGS. 2 to 3 at first, each pixel P of the light emitting display according to the present disclosure may be defined by a scan line SL, a data line DL and a driving current line VDD. Each pixel P of the light emitting display may include a switching thin film transistor ST, a driving thin film transistor DT, a light emitting diode OLE and a storage capacitance (or capacitor) Cst. The driving current line VDD may be supplied with a high-level voltage for driving the light emitting diode OLE.

A switching thin film transistor ST and a driving thin film transistor DT may be formed on a substrate 110. For example, the switching thin film transistor ST may be configured to be connected to the scan line SL and the data line DL. The switching thin film transistor ST may include a gate electrode SG, a semiconductor layer SA, a source electrode SS and a drain electrode SD. The gate electrode SG of the switching thin film transistor ST may be a portion of the scan line SL. The semiconductor layer SA may be disposed as crossing the gate electrode SG. The overlapped portion of the semiconductor layer SA with the gate electrode SG may be defined as the channel area. The source electrode SS may be branched from or connected to the data line DL, and the drain electrode SD may be connected to the driving thin film transistor DT. The source electrode SS may be one side of the semiconductor layer SA from the channel area, and the drain electrode SD may be the other side of the semiconductor layer SA. By supplying the data signal to the driving thin film transistor DT, the switching thin film transistor ST may play a role of selecting a pixel P which would be driven.

The driving thin film transistor DT may play a role of driving the light emitting diode OLE of the selected pixel P by the switching thin film transistor ST. The driving thin film transistor DT may include a gate electrode DG, a semiconductor layer DA, a source electrode DS and a drain electrode DD. The gate electrode DG of the driving thin film transistor DT may be connected to the drain electrode SD of the switching thin film transistor ST. For example, the gate electrode DG of the driving thin film transistor DT may be extended from the drain electrode SD of the switching thin film transistor ST. In the driving thin film transistor DT, the drain electrode DD may be branched from or connected to the driving current line VDD, further, the source electrode DS may be connected to the anode electrode (or pixel electrode) ANO of the light emitting diode (or light emitting element) OLE. The semiconductor layer DA may be disposed as crossing over the gate electrode DG. In the semiconductor layer DA, the overlapped portion with the gate electrode DG may be defined as a channel area. The source electrode DS may be connected at one side of the semiconductor layer DA around the channel area, and the drain electrode DD is connected to the other side of the semiconductor layer DA. A storage capacitance (or, capacitor) Cst may be disposed between the gate electrode DG of the driving thin film transistor DT and the anode electrode ANO of the light emitting diode OLE.

The light emitting diode OLE may generate light according to the current controlled by the driving thin film transistor DT. The driving thin film transistor DT may control the amount of current flowing from the driving current line VDD to the light emitting diode OLE according to the voltage difference between the gate electrode DG and the source electrode DS.

The light emitting diode OLE may include an anode electrode ANO, an emission layer, and a cathode electrode. The light emitting diode OLE may emit lights according to the current controlled by the driving thin film transistor DT. In other words, the light emitting diode OLE may provide an image by emitting light according to the current controlled by the driving thin film transistor DT. The anode electrode ANO of the light emitting diode OLE may be connected to the source electrode DS of the driving thin film transistor DT. The cathode electrode (or, common electrode) may be low-power line VSS supplied with the low-potential voltage. Therefore, the light emitting diode OLE may be driven by the electric current flown from the driving current line VDD to the low power line VSS controlled by the driving thin film transistor DT.

A plurality of pixels P may be arrayed on the substrate 110. For example, along the horizontal direction, a red pixel RP, a green pixel GP and a blue pixel BP may be sequentially arrayed and disposed. The combination of the red pixel RP, the green pixel GP and the blue pixel BP may configure one pixel. In another case, the red pixel, the green pixel, the white pixel and the blue pixel may be sequentially arrayed along the horizontal direction. The red pixel, the green pixel, the white pixel and the blue pixel may form a unit pixel. FIG. 3 shows that three pixels P, including a red pixel RP, a green pixel GP and a blue pixel BP are sequentially arrayed along the horizontal direction.

A plurality of slits SLT may be formed between pixels P, with one-by-one correspondence. The slit SLT may be formed on the upper surface of the cover plate CG. The slit SLT may have a line segment shape extending from the top to the bottom of the display area AA excepting the non-display area NDA. That is, the slit SLT may be disposed between two neighboring pixels P in the horizontal direction (or the first direction). The slit SLT may be not disposed between two pixels P neighboring in the vertical direction (or the second direction). In another example, the slit SLT may be disposed between two pixels P neighboring in the vertical direction (or the second direction), and the slit SLT may be not placed between two pixels P neighboring in the horizontal direction (or the first direction). When the slit SLT may be placed in both the horizontal direction (or first direction) and vertical direction (or second direction), the cover plate CG may be damaged or cut off, so the slits SLT may be formed in only one selected direction.

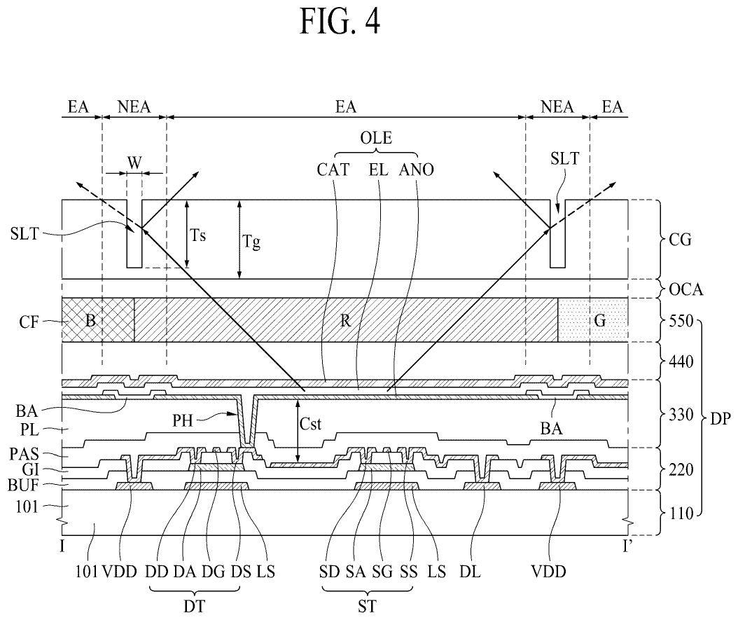

Referring to FIG. 4, a cross-sectional structure of the light emitting display device according to an embodiment of the present disclosure will be explained. FIG. 4 is a cross-sectional view along to cutting line I-I′ in FIG. 3, for illustrating a structure of one pixel in a light emitting display device according to an embodiment of the present disclosure. A light emitting display device may include a substrate 110, a driving element layer 220, a light emitting element layer 330, an encapsulation layer 440, a color filter layer CF and a cover plate CG. The driving element layer 220 may include a plurality of thin layers formed on the substrate 110. The driving element layer 220 may include a switching thin film transistor ST and a driving thin film transistor DT.

On the substrate 110, a data line DL, a driving current line VDD and a light shielding layer LS may be formed. The light shielding layer LS may be disposed in an island shape spaced apart from the data line DL and the driving current ling VDD by a selected distance and overlapping the semiconductor layers SA and DA. In some cases, the light shielding layer LS may be omitted.

A buffer layer BUF is deposited on entire surface of the substrate 110 as covering the driving current line VDD, the data line DL and the light shielding layer LS. On the buffer layer BUF, the semiconductor layer SA of the switching thin film transistor ST and the semiconductor layer DA of the driving thin film transistor DT are formed. The switching thin film transistor ST and the driving thin film transistor DT are formed on the buffer layer BUF. It is preferable that the channel areas in the semiconductor layers SA and DA overlap with the light shielding layer LS.

A gate insulating layer GI is deposited on the substrate 110 as covering the semiconductor layers SA and DA. A gate electrode SG overlapping with the semiconductor layer SA of the switching thin film transistor ST and the gate electrode DG overlapping with the semiconductor layer DA of the driving thin film transistor DT are formed on the gate insulating layer GI. In addition, at both sides of the gate electrode SG of the switching thin film transistor ST, a source electrode SS contacting one side of the semiconductor layer SA while being spaced apart from the gate electrode SG, and a drain electrode SD contacting the other side of the semiconductor layer SA are formed. Further, at both sides of the gate electrode DG of the driving thin film transistor DT, a source electrode DS contacting one side of the semiconductor layer DA while being spaced apart from the gate electrode DG, and a drain electrode DD contacting the other side of the semiconductor layer DA are formed.

The gate electrodes SG and DG and the source-drain electrodes SS-SD and DS-DD are formed on the same layer, but are spatially and electrically separated from each other. The source electrode SS of the switching thin film transistor ST may be connected to the data line DL via a contact hole penetrating the gate insulating layer GI. Further, the drain electrode DD of the driving thin film transistor DT may be connected to the driving current line VDD via another contact hole penetrating the gate insulating layer.

A passivation layer PAS is deposited on the substrate 110 as covering the thin film transistors ST and DT. The passivation layer PAS may be made of an inorganic material such as silicon oxide or silicon nitride.

The light emitting element layer 330 is formed on the driving element layer 220. The light emitting element layer 330 may include a planarization layer PL and a light emitting diode OLE. The planarization layer PL may be a layer used to flatten the uneven surface of the substrate 110 on which the thin film transistors ST and DT are formed. In order to equalize or compensate the height difference due to the uneven surface condition, the planarization layer PL may be formed of an organic material. A pixel contact hole PH may be formed at the passivation layer PAS and the planarization layer PL to expose a portion of the source electrode DS of the driving thin film transistor DT.

An anode electrode (or, pixel electrode) ANO may be formed on the top surface of the planarization layer PL. The anode electrode ANO may be connected to the source electrode DS of the driving thin film transistor DT via a pixel contact hole PH. The anode electrode ANO may have different structure and configuring elements according to the emission type of the light emitting diode OLE. For example, in the case of a bottom emission type that provides lights in the direction of the substrate 110, it may be formed of a transparent conductive material. For another example, in the case of a top emission type that provides lights in the upward direction facing the substrate 110, it may be formed of a metal material having excellent light reflectance. Otherwise, for the case of top emission type emitting light to the upper direction opposite the substrate 110, a reflective layer formed of a metal material with excellent light reflectance may be further included below or above the transparent layer formed of a transparent conductive material. In this disclosure, it will be explained where the anode electrode ANO may be formed of a reflective metal.

A bank BA is formed on the top surface of the substrate 110 having the anode electrode ANO. The bank BA is preferably an insulating layer made of an inorganic material or an organic material. Hereinafter, a case made of an in organic material will be described. The bank BA covers the circumferential areas of the anode electrode ANO, and exposes most of the middle area. The middle area exposed from the bank BA is defined as an emission area EA, and the area covered by bank BA is defined as a non-emission area NEA.

An emission layer EL is disposed on the anode electrode ANO and bank BA. The emission layer EL may be deposited on entire of the display area AA of the substrate 110 as covering the anode electrode ANO and the bank BA. For an example, the emission layer EL may include at least two emission parts for generating white light. In detail, the emission layer EL may include a first emission part and a second emission part vertically stacked for generating white light by mixing the first light from the first emission part and the second light from the second emission part.

For another example, the emission layer EL may include any one of a blue emission part, a green emission part, and a red emission part for generating light corresponding to a color set in each pixel. Further, the light emitting diode OLE may include a functional layer for improving light emitting efficiency and/or lifetime of the emission layer EL.

A cathode electrode (or common electrode) CAT is deposited on the entire surface of the substrate 110 on which the emission layer is formed. The cathode electrode CAT is deposited to make surface contact with the emission layer EL. The cathode electrode CAT is formed over the entire substrate 110 to be commonly connected to the emission layer EL deposited in all pixels. In the case of the top emission type, the cathode electrode CAT may include a transparent conductive material. For example, the cathode electrode CAT may be made of a transparent conductive material such as indium-tin-oxide (ITO) or indium-zinc-oxide (IZO). Alternatively, the cathode electrode CAT may include a thin metal such as aluminum (Al), magnesium (Mg), calcium (Ca), silver (Ag) or an alloy or combination thereof (e.g., aluminum-magnesium alloy (AlMg)). It may be formed to have light-transmitting characteristics by forming it with a thin thickness in a range of 20 Å to 300 Å. For the case of bottom emission type, the cathode electrode CAT may be made of a metal material having excellent light reflectance with 2,000 Å or more thickness. The metal material having excellent light reflectance may include any one of aluminum (Al), magnesium (Mg), calcium (Ca), silver (Ag) or an alloy or combination thereof (e.g., aluminum-magnesium alloy (AlMg)).

An encapsulation layer 440 is stacked on the light emitting element 220. The encapsulation layer 440 may have a single-layer structure made of an inorganic material, or a multi-layer structure in which several inorganic layers are sequentially stacked. As another example, the encapsulation layer 440 may have a structure in which an inorganic layer, an organic layer and an inorganic layer are continuously stacked. Here, for convenience of description, the encapsulation layer 440 made of a single inorganic layer will be used for explanation.

A color filter layer 550 is stacked on the encapsulation layer 440. In the color filter layer 550, a plurality of color filters CF may be arranged in a matrix manner to correspond to the arrangement of the pixels P. The color filter CF may be disposed with a structure in which one of a red color filter, a green color filter and a blue color filter is assigned to each pixel P. As another example, the color filter CF may be disposed with a structure in which one of a red color filter, a white color filter, a green color filter and a blue color filter is allocated to each pixel P. Hereinafter, for convenience of description, a case, in which the color filter CF includes a red color filter R, a green color filter G and a blue color filter B, representing the triple primary color light, is used for explanation.

A cover plate CG may be disposed on the color filter layer 550. The cover plate CG may be surface adhered to the color filter layer 550 with an optical adhesive layer OCA there-between. The cover plate CG may be formed of a transparent material with a refractive index of 1.5 or higher. For example, the cover plate CG may be made of transparent glass or transparent plastic.

In ultra-high-resolution light emitting display devices of 4K PPI or higher, especially in the case of personal immersive displays with a diagonal length of 5 inches or less and ultra-high resolution, it may be very difficult to form a black matrix to prevent color mixing between two neighboring color filters due to limitations in the manufacturing process. Therefore, in order to prevent color mixing between neighboring pixels, the thickness of the encapsulation layer 440 may be formed very thin, and then a color filter may be formed on the encapsulation layer 440. By forming the distance between the emission layer EL and the color filter layer 660 as closed as possible, color mixing at the boundaries of pixels may be minimized even though there is no black matrix. However, in order to ensure that the encapsulation layer 440 protects lower elements, there may be a limit to reducing the thickness of the encapsulation layer 440. Accordingly, there is a limit to minimizing the color mixing at the boundaries of pixels.

To overcome these limitations, in the cover plate CG of the light emitting display device according to the present disclosure, the slits SLT may be formed to the corresponding areas between two neighboring color filters. The slit SLT may be a trench shape formed by etching the cover plate CG to have a certain width W on the surface of the cover plate CG and a depth Ts smaller than the thickness Tg of the cover plate CG. Since the slit SLT is used to prevent light emitted from the emission layer EL from being transmitted to neighboring pixels, it may be desirable to have a width corresponding to the size of the bank BA.

The cover plate CG may be the most externally placed element in the light emitting display device according to the present disclosure. Therefore, the cover plate CG may be in contact with air. Accordingly, the inside of the slit SLT may be filled with air (or in some embodiments, air may be present inside the slit SLT). That is, the side of the slit SLT may become a vertical interface where the cover plate CG and air meet. Therefore, most of the light emitted from the emission layer EL and directed to the slit SLT may be reflected on the vertical plane of the slit SLT due to the difference in refractive index between the cover plate CG and air. In the case without slit SLT, the light passing through the red color filter R may proceed from the cover plate CG to the upper area of the blue color filter B or the upper area of the green color filter G, resulting in color mixing. In the light emitting display device according to the present disclosure shown in FIG. 4, due to the slit SLT, most of the light passing through the red color filter R may transmitted and/or reflected to the upper part of the red color filter R on the cover plate CG. Accordingly, the color mixing may not occur and color reproducibility or color purity may be improved.

The light emitting display device according to the present disclosure may have the feature of arranging slits on the cover glass in a structure in which it is difficult to form a black matrix between color filters. As the result, this structure may prevent the problem of color purity deterioration due to diffusely reflected light caused by the bank BA or pixel defining layer formed at the boundary of the color filter, and the problem of the color reproducibility deterioration due to color mixing between neighboring pixels, resulting in providing excellent image quality.

Hereinafter, a light emitting display device having a cover plate CG on which slits SLT of various shapes are formed will be described using various embodiments of the present disclosure.

### First Exemplary Aspect

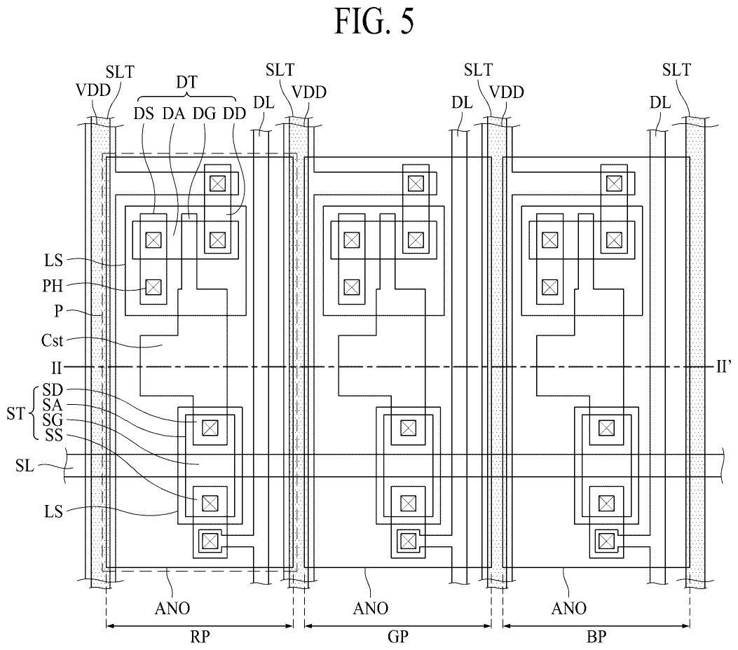

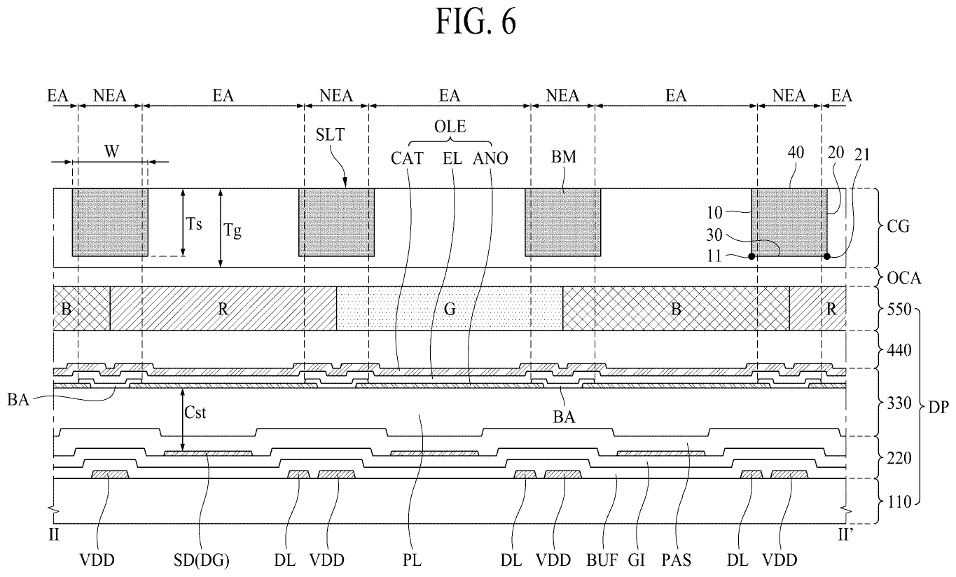

Referring to FIGS. 5 and 6, a first exemplary aspect of the present disclosure will be explained. FIG. 5 is a plan view illustrating a structure of three pixels sequentially arrayed in a light emitting display device according to a first embodiment of the present disclosure. FIG. 6 is an enlarged cross-sectional view, cutting along line II-II′ of FIG. 5, for illustrating a structure of three pixels sequentially arrayed in a light emitting display device according to a first embodiment of the present disclosure. The descriptions for the structure from the substrate 110 to the color filter 550 may be omitted or simply explained since the cross-sectional structure of them is the same as previously described with FIG. 4. As for the reference numerals shown in the drawings even though not explained may be referred to the description in FIG. 4.

The light emitting display device according to a first exemplary aspect of the present disclosure may comprise a display panel DP and a cover plate CG covering the display panel DP. The display panel DP may include a substrate 110, a driving element layer 220, a light emitting element layer 330, an encapsulation layer 440 and a color filter layer 550. The driving element layer 220 may include a data line DL, a scan line SL, a driving current line VDD, a switching thin film transistor ST and a driving thin film transistor DT. The light emitting element layer 330 may include an anode electrode ANO, an emission layer EL and a cathode electrode CAT. The anode electrode ANO of the light emitting element layer 330 may be connected to the driving thin film transistor DT formed in the driving element layer 220. The encapsulation layer 440 made of a single-layered inorganic layer may be deposited on the light emitting element layer 330. The color filter layer 550 may be disposed on the encapsulation layer 440.

The color filter layer 550 may include a red color filter R, a green color filter G and a blue color filter B which are arranged sequentially, and one of them assigned to each pixel. For the case in which a light emitting display device with an ultra-high-resolution of 4K PPI or more and a diagonal length of 5 inches or less, such as a personal immersive display device, it may be very difficult to dispose a black matrix between color filters. Accordingly, the red color filter R, the green color filter G and the blue color filter B may be arranged in succession while directly contacting each other.

The cover plate CG may be disposed on the color filter layer 550. The cover plate CG may be in surface adhere to the color filter layer 660 using an optical adhesive layer OCA there-between. The cover plate CG may be made of a transparent material having a refractive index of 1.5 or more.

When the black matrix is not disposed, color mixing between pixels may be minimized by thinning the thickness of the encapsulation layer 440. However, in order to ensure the function of the encapsulation layer 440, a certain thickness should be maintained, so there is a limitation to reducing the color mixing. As another problem, a light emission phenomenon may occur in the bank BA disposed between two neighboring pixels P due to the light emitted from the emission layer EL. The light emitted from the bank BA may cause a deterioration of color purity of the light emitted within the normal pixel area.

In order to solve these problems, in the first exemplary aspect of the present disclosure, the thickness of the encapsulation layer 440 may be not formed to be thinned, but instead, the light emitting display device may have a structure in which a plurality of slits SLT may be arranged with regular intervals on the cover plate CG. For example, the slits SLT may be disposed in the display area AA in FIG. 2 and may be disposed one by one between pixels P along the Y axis. The slit SLT may have a trench shape formed by etching the cover plate CG to have a certain width W on the surface of the cover plate CG and a depth Ts smaller than the thickness Tg of the cover plate CG. For example, the depth Ts of the slit SLT may be 80% to 95% of the thickness Tg of the cover plate CG.

The slit SLT may be disposed directly above the bank BA and overlap the bank BA. Since the slit SLT may be intended to prevent light reflected and/or refracted by the bank BA from going out, it is desirable to have a width corresponding to the size of the bank BA. The width of the slit SLT may be equal to or slightly larger than the width of the bank BA. In addition, the banks BA may be overlapped with the slit SLT so that the banks BA may be completely covered by the slits SLT. By disposing the slit SLT on the bank BA, the slit SLT may prevent light emitted from the emission layer EL and scattered by the bank BA from being emitted to the outside. For example, the width W of the slit SLT may be 5% to 10% larger than the width of the bank BA.

From the cross-sectional view, the slit SLT may include a first side surface 10, a second side surface 20, a bottom surface 30 and a top surface 40. The first side surface 10 may be a side wall extending from the upper surface of the cover plate CG to the first end 11 recessed by the depth Ts in the direction toward the lower surface. The second side surface 20 may be a side wall extending from the upper surface of the cover plate CG to the second end 21 that is spaced apart by the width W from the first side surface 10 and is recessed by the depth Ts, to be opposite the first side surface 10. The bottom surface 30 may be a surface extending from the first end 11 to the second end 21. The top surface 40 may face the bottom surface 30 and may be a surface set on the upper surface of the cover plate CG. In the first exemplary aspect, the cross-sectional shape of the slit SLT may have a right angled rectangular shape in which the first side surface 10 and the second side surface 20 are parallel to each other, and the bottom surface 30 and the top surface 40 are parallel to each other.

In the first exemplary aspect, the inside of the slit SLT may be filled with a light absorbing material (or in some embodiments, light absorbing material may be present inside the slit SLT). For example, the light absorbing material may be a black resin material. Accordingly, the slit SLT filled with the light absorbing material may be a black matrix BM which is disposed between neighboring two pixels P, especially between two neighboring color filters. The black matrix BM may include the first side surface 10, the second side surface 20, the bottom surface 30 and the top surface 40.

Since the black matrix BM is disposed on the bank BA, the black matrix BM may completely block the light scattered from the bank BA. That is, it is expected to prevent the problem of color purity deterioration caused by light scattered from the bank BA. In addition, the slit SLT filled with the light absorbing material may block the light which is emitted from the emission layer EL of one pixel and enters into a neighboring pixel, thereby preventing the color mixing at the boundaries of the pixels P.

The black resin for the light absorbing material may have a lower refractive index than the cover plate CG. For example, when the cover plate CG is made of glass, the cover plate CG may have a refractive index of 1.5, so the light absorbing material may be made of a black resin with a refractive index of 1.2 to 1.3. For another example, when the cover plate CG is made of a plastic material with a refractive index of 1.7 to 1.9, the black matrix BM may be made of a black resin with a refractive index of 1.2 to 1.4.

The black matrix BM may be disposed between two neighboring color filters. Therefore, the light emitted from the emission layer EL, passing through the color filter and then reached to the slit SLT may be reflected and refracted due to the difference in refractive index between the cover plate CG and the black matrix BM filling the slit SLT. Among these lights, those that satisfy the total reflection conditions may be reflected and return to the pixel area from which the light is firstly emitted. Meanwhile, the refracted light that may bot satisfy the total reflection condition may be absorbed by the black matrix BM and may not proceed to the neighboring pixels. Accordingly, color mixing between neighboring pixels may be almost completely prevented, and color reproduction may be improved.

The light emitting display device according to the first exemplary aspect may have a structure in which a black matrix BM may be further formed by filling the inside of the slit SLT with a black resin material in the case described in FIG. 4. For the case of FIG. 4, since only the slit SLT exists, light that may be not blocked by the slit SLT or may not satisfy the total reflection condition may leak, causing deterioration of image quality. However, in the first exemplary aspect, since the slit SLT may be filled with a black resin material, most light that may be not blocked by the slit SLT or may not satisfy the total reflection condition may be absorbed, thereby improving color purity and color reproduction rate.

### Second Exemplary Aspect

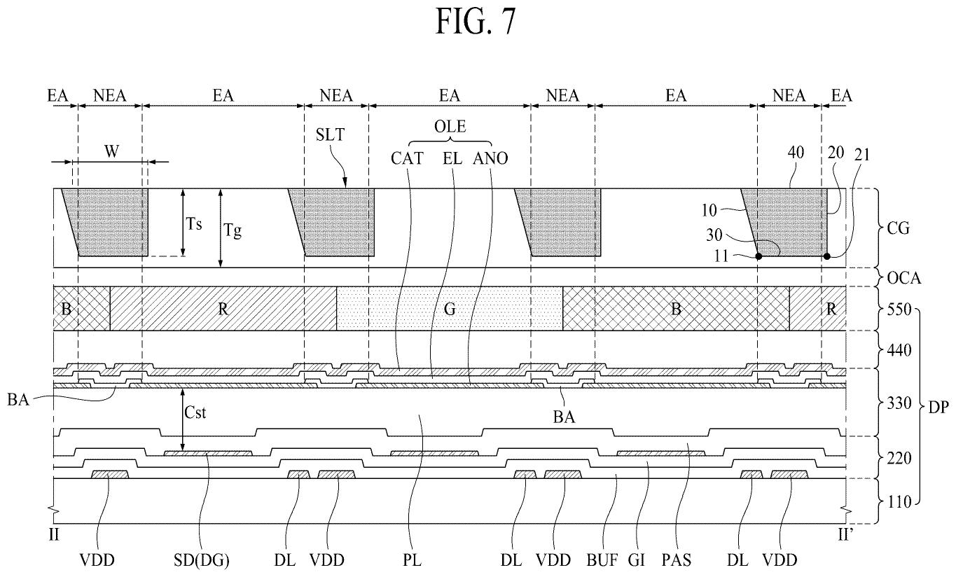

Hereinafter, referring to FIG. 7, second exemplary aspect of the present disclosure will be explained. FIG. 7 is an enlarged cross-sectional view, cutting along line II-II′ of FIG. 5, for illustrating a structure of three pixels sequentially arrayed in a light emitting display device according to a second embodiment of the present disclosure. The descriptions for the structure from the substrate 110 to the color filter 550 may be omitted or simply explained since the cross-sectional structure of them is the same as previously described with FIG. 4 or FIG. 6. As for the reference numerals shown in the drawings even though not explained may be referred to the description in FIG. 4 or FIG. 6.

The light emitting display device according to a second exemplary aspect of the present disclosure may comprise a display panel DP and a cover plate CG covering the display panel DP. The display panel DP may include a substrate 110, a driving element layer 220, a light emitting element layer 330, an encapsulation layer 440 and a color filter layer 550. The driving element layer 220 may include a data line DL, a scan line SL, a driving current line VDD, a switching thin film transistor ST and a driving thin film transistor DT. The light emitting element layer 330 may include an anode electrode ANO, an emission layer EL and a cathode electrode CAT. The anode electrode ANO of the light emitting element layer 330 may be connected to the driving thin film transistor DT formed in the driving element layer 220. The encapsulation layer 440 made of a single-layered inorganic layer may be deposited on the light emitting element layer 330. The color filter layer 550 may be disposed on the encapsulation layer 440.

The color filter layer 550 may include a red color filter R, a green color filter G and a blue color filter B which are arranged sequentially, and one of them assigned to each pixel. For the case in which a light emitting display device with an ultra-high-resolution of 4K PPI or more and a diagonal length of 5 inches or less, such as a personal immersive display device, it may be very difficult to dispose a black matrix between color filters. Accordingly, the red color filter R, the green color filter G and the blue color filter B may be arranged in succession while directly contacting each other.

The cover plate CG may be disposed on the color filter layer 550. The cover plate CG may be in surface adhere to the color filter layer 660 using an optical adhesive layer OCA there-between. The cover plate CG may be made of a transparent material having a refractive index of 1.5 or more.

Like the first exemplary aspect, the second exemplary aspect may have a structure in which a plurality of slits SLT may be arranged with regular intervals on the cover plate CG. The slit SLT may have a trench shape formed by etching the cover plate CG to have a certain width W on the surface of the cover plate CG and a depth Ts smaller than the thickness Tg of the cover plate CG. For example, the depth Ts of the slit SLT may be 80% to 95% of the thickness Tg of the cover plate CG. The slit SLT may be disposed directly above the bank BA and overlap the bank BA.

From the cross-sectional view, the slit SLT may include a first side surface 10, a second side surface 20, a bottom surface 30 and a top surface 40. The first side surface 10 may be a side wall extending from the upper surface of the cover plate CG to the first end 11 recessed by the depth Ts in the direction toward the lower surface. The second side surface 20 may be a side wall extending from the upper surface of the cover plate CG to the second end 21 that is spaced apart by the width W form the first side surface 10 and is recessed by the depth Ts, to be opposite the first side surface 10. The bottom surface 30 may be a surface extending from the first end 11 to the second end 21. The top surface 40 may face the bottom surface 30 and may be a surface set on the upper surface of the cover plate CG.

The inside of the slit SLT may be filled with a light absorbing material. For example, the light absorbing material may be a black resin material. Accordingly, the slit SLT filled with the light absorbing material may be a black matrix BM which is disposed between neighboring two pixels P, especially between two neighboring color filters. The black matrix BM may include the first side surface 10, the second side surface 20, the bottom surface 30 and the top surface 40.

Since the black matrix BM is disposed on the bank BA, the black matrix BM may completely block the light scattered from the bank BA. That is, it is expected to prevent the problem of color purity deterioration caused by light scattered from the bank BA. In addition, the slit SLT filled with the light absorbing material may block the light which is emitted from the emission layer EL of one pixel and enters into a neighboring pixel, thereby preventing the color mixing at the boundaries of the pixels P.

The structure of the light emitting display device according to the second exemplary aspect may be almost the same as that of the light emitting display device according to the first exemplary aspect. There may be a difference in the cross-sectional shape of the slit SLT. The following description may be focused on the different features of the second exemplary aspect. Descriptions the same as those in the first exemplary aspect may be omitted or simply explained.

In the first exemplary aspect, the cross-sectional shape of the slit SLT may have a rectangular shape. Meanwhile, in the second exemplary aspect, the cross-sectional shape of the slit SLT may have a trapezoidal shape. For example, the second side surface 20 may be a vertical surface deeply grooved in a direction perpendicular to the surface of the cover plate CG. The first side surface 10 may be a deeply grooved and inclined surface having a selected angle with respect to the surface of the cover plate CG.

In detail, the first side surface 10 of the slit SLT for the second exemplary aspect may be a slanted surface inclined at a certain angle (different from vertical angle) with respect to the surface of the cover plate CG. On the other hand, the second side surface 20 may be a vertical plane. In FIG. 7, the first side surface 10 which is an inclined surface may be disposed at the left side, and the second side surface 20 which is a vertical surface may be placed on the right side. However, it is not limited thereto, the first side surface 10 which is an inclined surface may be disposed at the right side, and the second side surface 20 which is the vertical surface may be placed at the left side. For another example, both of the first side surface 10 and the second side surface 20 may be inclined surfaces.

Depending on the inclination direction of the slanted surface, the top surface 40 may have a larger or narrower area than the bottom surface 30. When the top surface 40 has a larger area than the bottom surface 30, due to the shape of the slit SLT, in particular, in proportion to the degree of inclination of the first side surface 10 which is the slanted surface, the light emitted from the emission layer EL may be deflected in the direction where the inclined surface is disposed, i.e., in the left direction in FIG. 7. For another example, when both the first side surface 10 and the second side surface 20 are slanted (or inclined surfaces, the light emitted from the emission layer EL may be concentrated in the central area of the pixel (when the size of the top surface 40 may be smaller than the bottom surface 30), or the light may be widely spread to the edge direction (when the size of the top surface 40 may be larger than the bottom surface 30).

In the light emitting display device according to the second exemplary aspect, by filling the slit SLT with a black resin material, the lights that may not be blocked by the slit SLT or that may not satisfy the total reflection conditions may be absorbed. As the result, color purity and color reproduction rate may be further improved. In addition, unlike the case described in FIG. 5 showing the first exemplary aspect, there is a different feature in that it is provided with a slanted surface inclined in one direction. With this feature, there is an effect of deflecting the direction of light emitted from the emission layer EL in one direction. For example, by applying the light emitting display device according to the second exemplary aspect to a personal immersive display device, there is an effect of biasing the image information provided from the pixels to focus on the user's left eye and right eye, respectively. For another example, when applying the second exemplary aspect to a monitor mounted on a car dashboard, the effect of providing a specific image only to a specific person may be achieved by biasing the image information toward the driver seat or toward the passenger seat.

### Third Embodiment

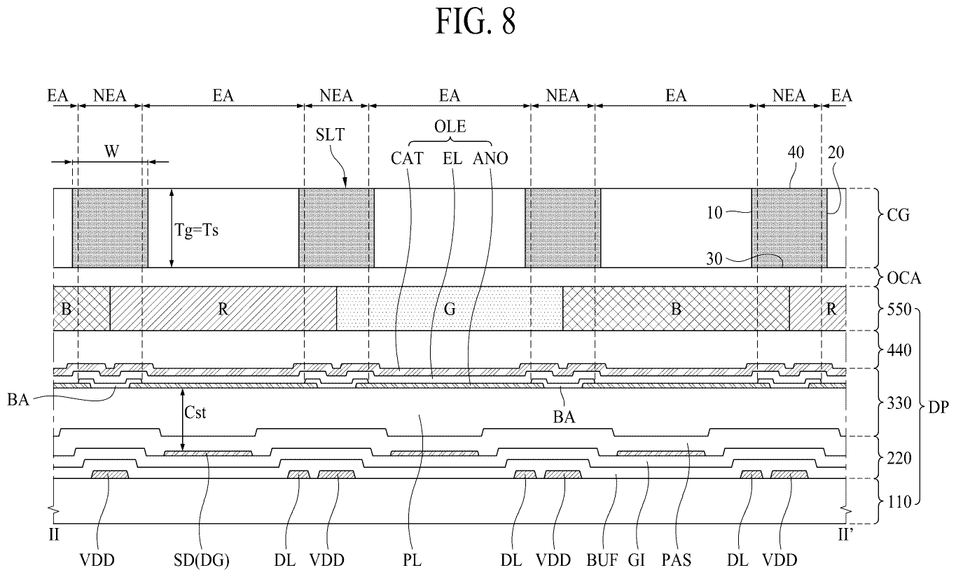

Hereinafter, referring to FIG. 8, a third exemplary aspect of the present disclosure will be explained. FIG. 8 is an enlarged cross-sectional view, cutting along line II-II′ of FIG. 5, for illustrating a structure of three pixels sequentially arrayed in a light emitting display device according to a third embodiment of the present disclosure. The descriptions for the structure from the substrate 110 to the color filter 550 may be omitted or simply explained since the cross-sectional structure of them is the same as previously described with FIG. 4. As for the reference numerals shown in the drawings even though not explained may be referred to the description in FIG. 4.

The light emitting display device according to a first exemplary aspect of the present disclosure may comprise a display panel DP and a cover plate CG covering the display panel DP. The display panel DP may include a substrate 110, a driving element layer 220, a light emitting element layer 330, an encapsulation layer 440 and a color filter layer 550. The driving element layer 220 may include a data line DL, a scan line SL, a driving current line VDD, a switching thin film transistor ST and a driving thin film transistor DT. The light emitting element layer 330 may include an anode electrode ANO, an emission layer EL and a cathode electrode CAT. The anode electrode ANO of the light emitting element layer 330 may be connected to the driving thin film transistor DT formed in the driving element layer 220. The encapsulation layer 440 made of a single-layered inorganic layer may be deposited on the light emitting element layer 330. The color filter layer 550 may be disposed on the encapsulation layer 440.

The color filter layer 550 may include a red color filter R, a green color filter G and a blue color filter B which are arranged sequentially, and one of them assigned to each pixel. For the case in which a light emitting display device with an ultra-high-resolution of 4K PPI or more and a diagonal length of 5 inches or less, such as a personal immersive display device, it may be very difficult to dispose a black matrix between color filters. Accordingly, the red color filter R, the green color filter G and the blue color filter B may be arranged in succession while directly contacting each other.

The cover plate CG may be disposed on the color filter layer 550. The cover plate CG may be in surface adhere to the color filter layer 660 using an optical adhesive layer OCA there-between. The cover plate CG may be made of a transparent material having a refractive index of 1.5 or more.

Like the first exemplary aspect, the third exemplary aspect may have a structure in which a plurality of slits SLT may be arranged with regular intervals on the cover plate CG. The inside of the slit SLT may be filled with a black resin material. Accordingly, the slit SLT filled with the light absorbing material may be a black matrix BM which is disposed between neighboring two pixels P, especially between two neighboring color filters. Since the black matrix BM is disposed on the bank BA, the black matrix BM may completely block the light scattered from the bank BA. That is, it is expected to prevent the problem of color purity deterioration caused by light scattered from the bank BA. In addition, the slit SLT filled with the light absorbing material may block the light which is emitted from the emission layer EL of one pixel and enters into a neighboring pixel, thereby preventing the color mixing at the boundaries of the pixels P.

The structure of the light emitting display device according to the third exemplary aspect may be almost the same as that of the light emitting display device according to the first exemplary aspect. There may be a difference in the cross-sectional shape of the slit SLT.

In the first exemplary aspect, the slit SLT may have a trench shape formed by etching the cover plate CG to have a certain width W on the surface of the cover plate CG and a depth Ts smaller than the thickness Tg of the cover plate CG. Meanwhile, in the third exemplary aspect, the slit SLT may have a through-bar shape formed by etching the cover plate CG to have a certain width W on the surface of the cover plate CG and a depth Ts equal to the thickness Tg of the cover plate CG. That is, in the third exemplary aspect, the depth Ts of the slit SLT may be 100% of the thickness Tg of the cover plate CG.

The slit SLT may be disposed directly above the bank BA and overlap the bank BA. The width of the slit SLT may be equal to or slightly larger than the width of the bank BA. The banks BA may be overlapped with the slit SLT so that the banks BA may be completely covered by the slits SLT. For example, the width W of the slit SLT may be 5% to 10% larger than the width of the bank BA.

From the cross-sectional view, the slit SLT may include a first side surface 10, a second side surface 20, a bottom surface 30 and a top surface 40. In FIG. 7, the cross-sectional shape of the slit SLT may have the same rectangular shape as the first exemplary aspect. However, it is not limited thereto, the cross-sectional shape of the slit SLT may have a trapezoidal shape, as in the second exemplary aspect.

The inside of the slit SLT may be filled with a light absorbing material. The slit SLT filled with the light absorbing material may be a black matrix BM which is disposed between neighboring two pixels P, especially between two neighboring color filters. The black resin for the light absorbing material may have a refractive index less than that of the cover plate CG.

In the third exemplary aspect, since the slit SLT is filled with the black resin material, by absorbing lights that may not be blocked by the slit SLT or may not satisfy the total reflection conditions, the color purity and color reproduction property may be further improved.

In the first exemplary aspect, a portion of the transparent cover plate CG remains at the bottom of the slit SLT filled with the black matrix BM, so light may leak through this portion. However, in the third exemplary aspect, since the black matrix BM may have the same thickness as the cover plate CG, the color mixing between neighboring pixels may be more completely blocked.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment may be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description. In general, in the following claims, the terms used should not be construed to limit the claims to the specific example embodiments disclosed in the specification and the claims, but should be construed to include all possible embodiments along with the full scope of equivalents to which such claims are entitled. Accordingly, the claims are not limited by the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display device comprising:
a display panel including a plurality of pixels;
a cover plate covering the display panel;
a slit disposed between two pixels neighboring in a first direction on the cover plate; and
a light absorbing material,
wherein the slit has the light absorbing material therein.

2. The light emitting display device according to claim 1, wherein the slit has a depth equal to or smaller than a thickness of the cover plate.

3. The light emitting display device according to claim 2, wherein the depth of the slit is 80% to 100% of the thickness of the cover plate.

4. The light emitting display device according to claim 2, wherein the slit includes:
a first side surface extending from an upper surface of the cover plate to a first end recessed a selected depth along a direction of the depth;
a second side surface separated from the first side surface with a selected width, extending from the upper surface of the cover plate to a second end recessed the selected depth along the direction of the depth, and facing the first side surface;
a bottom surface extending from the first end to the second end; and
a top surface facing the bottom surface and setting on the upper surface of the cover plate.

5. The light emitting display device according to claim 4, wherein the first side surface and the second side surface are parallel to each other, as vertical surfaces.

6. The light emitting display device according to claim 4, wherein any one of the first side surface and the second side surface is a slanted plane, and the other is a vertical plane.

7. The light emitting display device according to claim 4, wherein the first side surface and the second side surface are slanted planes.

8. The light emitting display device according to claim 4, wherein a size of the top surface is different from a size of the bottom surface.

9. The light emitting display device according to claim 1, wherein the display panel includes:
an anode electrode disposed on each pixel;
a bank covering circumference of the anode electrode;
an emission layer disposed on the anode electrode; and
a cathode electrode disposed on the emission layer,
wherein the slit has a width corresponding to the bank.

10. The light emitting display device according to claim 9, wherein the slit has a width 5% to 10% wider than the bank, and
wherein the bank is overlapped with a middle portion of the slit.

11. The light emitting display device according to claim 1, wherein the display panel includes:
a substrate;
a driving element layer disposed on the substrate;
a light emitting element layer disposed on the driving element layer;
an encapsulation layer disposed on the light emitting element layer; and
a color filter layer disposed on the encapsulation layer,
wherein the cover plate is adhered on the color filter layer with a transparent optical adhesive.

12. The light emitting display device according to claim 11, wherein the color filter layer includes a first color filter, a second color filter, and a third color filter corresponding to each pixel, and
wherein the slit is disposed between the first color filter and the second color filter, between the second color filter and the third color filter, and between the third color filter and the first color filter.

13. The light emitting display device according to claim 1, wherein the light absorbing material has a refractive index less than the cover plate.

14. The light emitting display device according to claim 13, wherein the cover plate includes a transparent material of which refractive index is 1.5 to 1.9, and
wherein the light absorbing material includes a black resin material of which refractive index is 1.2 to 1.4.

15. The light emitting display device according to claim 1, wherein the display panel includes:
a display area configured to provide video images; and
a non-display area adjacent to the display area,
wherein the cover plate has an area larger than the display area and is disposed on the display area, and
wherein the slit is disposed within the display area on the cover plate.

16. The light emitting display device according to claim 1, wherein the plurality of pixels is arrayed in a matrix manner.
